(19) United States
(12) Patent Application Publication
(10) Pub. No.: US 2021/0125741 A1
(43) Pub. Date: Apr. 29, 2021

(54) Graphene Oxide-Filled Polyimide Films and Process

(71) Applicant: Nanotek Instruments, Inc., Dayton, OH (US)

(72) Inventors: Ming-Siao Hsiao, Beavercreek, OH (US); Aruna Zhamu, Springboro, OH (US); Bor Z. Jang, Centerville, OH (US)

(73) Assignee: Nanotek Instruments, Inc., Dayton, OH (US)

(21) Appl. No.: 15/915,892

(22) Filed: Mar. 8, 2018

Related U.S. Application Data
(63) Continuation-in-part of application No. 15/170,387, filed on Jun. 1, 2016, now Pat. No. 9,959,948.
Application No. 15/170,387 is a division of application No. 13/999,761, filed on Mar. 20, 2014, now Pat. No. 9,359,208.

(51) Int. Cl. H01B 1/04; C01B 32/182; C01B 32/20; C09K 5/14; H05K 9/00

(52) U.S. Cl. CPC H01B 1/04; C01B 32/182; C01B 32/20; H05K 9/0073; Y10T 428/30; C09K 5/14

(57) ABSTRACT

Provided is a process for producing a graphene oxide platelet-filled polyimide film comprising the steps of: (a) mixing graphene oxide platelets with a polyimide precursor material and a liquid to form a slurry; (b) forming a wet film from said slurry; (c) partially or completely removing the liquid from the wet film to form a precursor polyimide composite film; and (d) imidizing the precursor polyimide composite film to approximately 90% or more completion of the crosslinking reaction, to obtain a graphene oxide platelet-filled composite film.

This application is a continuation-in-part of U.S. patent application Ser. No. 15/170,387, which is a divisional of U.S. patent application Ser. No. 13/999,761 (filed Mar. 20, 2014), which is now U.S. Pat. No. 9,359,208 (issued Jun. 7, 2016), the contents of which are incorporated by reference herein, in their entirety, for all purposes.

### FIELD OF THE INVENTION

The present disclosure relates generally to the field of polymer materials and, more particularly, to a translucent or opaque polyimide film having a low dielectric constant and/or high dielectric strength, obtained from a graphene oxide-filled polymer precursor.

### BACKGROUND OF THE INVENTION

Electronic devices sometimes require opaque covering films having a low dielectric constant and high dielectric strength. Carbon black filled polyimide is one example of an opaque covering film. Toughness, low dielectric constant, high dielectric strength, opacity, and matte surface finish are desirable features of these films. High thermal conductivity (as compared to an unfilled polymer film) is also desirable.

It is an object of the present disclosure to provide a process for producing translucent or opaque polymer films, and especially translucent or opaque polyimide films having a low dielectric constant, and suitable toughness.

### SUMMARY OF THE INVENTION

It is an object of the present disclosure to provide a process for producing translucent or opaque polymer films, and especially translucent or opaque polyimide films having a low dielectric constant, and suitable toughness for use in electronic packaging, including handheld electronic devices.

Herein presented is a process for producing a graphene oxide-filled polymer film comprising the steps of: (a) mixing graphene oxide platelets with a polymer precursor, a liquid (e.g. water or other solvent), and an optional curing agent to obtain a slurry (b) forming the slurry into a graphene oxide-filled precursor polymer composite film (c) optionally removing some or all of the liquid from the film, and (d) initiating a cure reaction of the graphene oxide-filled precursor polymer composite film.

The film-forming process may optionally be carried out under the influence of an orientation-inducing stress field, for example by using a slot-die head, comma coater head, or a pair of reverse-rotating rollers. The curing reaction may be initiated chemically, by heat, by exposure to radiation, or by light.

The step of forming said slurry into a wet film may be carried out by a doctor blade, slot die coating, comma coating, reverse-rollers coating, spray coating, spin coating, or screen printing and said step is optionally under the influence of an orientation-inducing stress field to align the graphene oxide platelets in the wet polymer film on a solid substrate. The resulting composite film may have the graphene oxide platelets being substantially parallel to each other.

The step of partially or completely removing the liquid from the wet film may be carried out in vacuum, in an inert atmosphere, in a ventilated environment, or at a temperature from 25° C. to 300° C.

The imidizing step is preferably carried out by exposure to a temperature from 100° C. to 500° C. for a period of time sufficient to effect crosslinking of said polymer and chemical bonding of said polymer to said graphene platelets, by exposure to light, by exposure to microwave energy, by exposure to radiation, or by combinations thereof. The period of time is preferably from 1 minute to 4 hours.

The process may further comprise a step of compressing or stretching the graphene oxide-filled polyimide film during or after said step (d) of imidizing said graphene oxide-filled polyimide film.

The process may further comprise a step of adding one or more additional layers of graphene oxide-filled polymer film after completing a first layer of graphene oxide-filled composite film, where the one or more additional layers have the same chemical composition as the first layer or have a different chemical composition.

The process may further comprise a step of adding one or more additional layers of precursor composite film after completing a first layer of precursor composite film, where said one or more additional layers have the same chemical composition as said first layer, or have a different chemical composition.

The process is preferably carried out as a continuous or roll-to-roll process.

The process polyimide precursor material may be selected from aromatic diamines, aliphatic diamines, and mixtures thereof in combination with aromatic dianhydrides.

The process slurry may further comprise a monomer, an oligomer, a polymer, a cure agent, a dehydrating agent, a photosensitizer, or a combination thereof.

The polymer may be selected from the group consisting of polyimide, polyamide, polyoxadiazole, polybenzoxazole, polybenzobisoxazole, polythiazole, polybenzothiazole, polybenzobisthiazole, poly(p-phenylene vinylene), polybenzimidazole, polybenzobisimidazole, and combinations thereof.

The slurry or suspension may further comprise a cure agent or anhydride selected from benzenetetracarboxylic dianhydride, biphenyltetracarboxylic dianhydride, diethylenetriaminepentaacetic dianhydride (DTPA), ethyl enediaminetetraacetic dianhydride (EDTA), mellitic acid dianhydride (MADA), naphthalenetetracarboxylic dianhydride, oxydibenzoic dianhydride, oxydiphthalic anhydride (ODPA), phthalic anhydride, pyromellitic dianhydride (PMDA), benzophenonetetracarboxylic dianhydride (BTDA), and combinations thereof.

The liquid may comprise water, acetone, γ-butyrolactone, chlorobenzene, cyclopentyl methyl ether, dihydrolevoglucosenone, dimethylacetamide (DMAc), ethanol, N-methyl-2-pyrrolidone (NMP), hexafluorisopropanol (HFIP), butylated hydroxytoluene (BHT), dimethylformamide (DMF), dimethylsulfoxide (DMSO), methanol, methyl acetate, methyl ethyl ketone, methylene chloride, piperazine, sodium trifluoroacetate (NaTFA), tert-butanol, tetrahydrofuran (THF), 1,2,4-trichlorobenzene (TCB), triethylamine (TEA), triethyl phosphate, toluene, derivatives thereof, and mixtures thereof.

The slurry or suspension may further comprise a matting agent, a colorant, a reinforcement material or other additive at total non-graphene oxide additive weight of 0.1 weight percent to 15 weight percent of the total weight of the dried film.

The disclosure also provides a graphene oxide-filled polyimide film made by the invented process described in the foregoing, having a thickness preferably from 1 μm to 200 μm (can be as thin as 10 nm or as thick as several mm.)

The graphene oxide-filled polyimide film may have a modulus from 2 to 3.5 GPa. The graphene oxide-filled polyimide film may have a dielectric strength greater than 5000 V/mil. The graphene oxide-filled polyimide film may have a dielectric strength from 3000 V/mil to 7000 V/mil.

The invention also provides a process for producing a graphene platelet-filled polymer film comprising the steps of: (a) mixing graphene platelets with a polymer precursor material and a liquid to form a slurry or suspension, wherein the graphene platelets are selected from graphene oxide, reduced graphene oxide, chemically reduced graphene oxide, fluorinated graphene, hydrogenated graphene, nitrogenated graphene, doped graphene, chemically functionalized graphene, and combinations thereof; (b) forming the slurry or suspension into a wet film; (c) partially or completely removing the liquid from the wet film to form a precursor polymer composite film; and (d) initiating a cure reaction of the film to obtain a graphene platelet-filled composite film.

The disclosure also provides a graphene platelet-reinforced polymer film. In the composite film, the graphene platelets may be substantially parallel to each other and, hence, exhibits a high elastic modulus, high tensile strength, and high dielectric strength.

### BRIEF DESCRIPTION OF THE DRAWINGS

FIG. 1 Schematic drawing illustrating the processes for producing paper, mat, film, and membrane of simply aggregated graphite or NGP flakes/platelets. All processes begin with intercalation and/or oxidation treatment of graphitic materials (e.g. natural graphite particles).

FIG. 2(A) A SEM image of a graphite worm sample after thermal exfoliation of graphite intercalation compounds (GICs) or graphite oxide powders;

FIG. 2 (B) An SEM image of a cross-section of a flexible graphite foil, showing many graphite flakes with orientations not parallel to the flexible graphite foil surface and also showing many defects, kinked or folded flakes.

FIG. 3 Representative chemical reactions involved in the formation of polyimide polymers.

FIG. 4 Chemical reactions associated with production of PBO.

FIG. 5(A) A process step of mixing graphene oxide in polyimide precursor material

FIG. 5(B) An example of a graphene oxide platelet-filled polyimide film

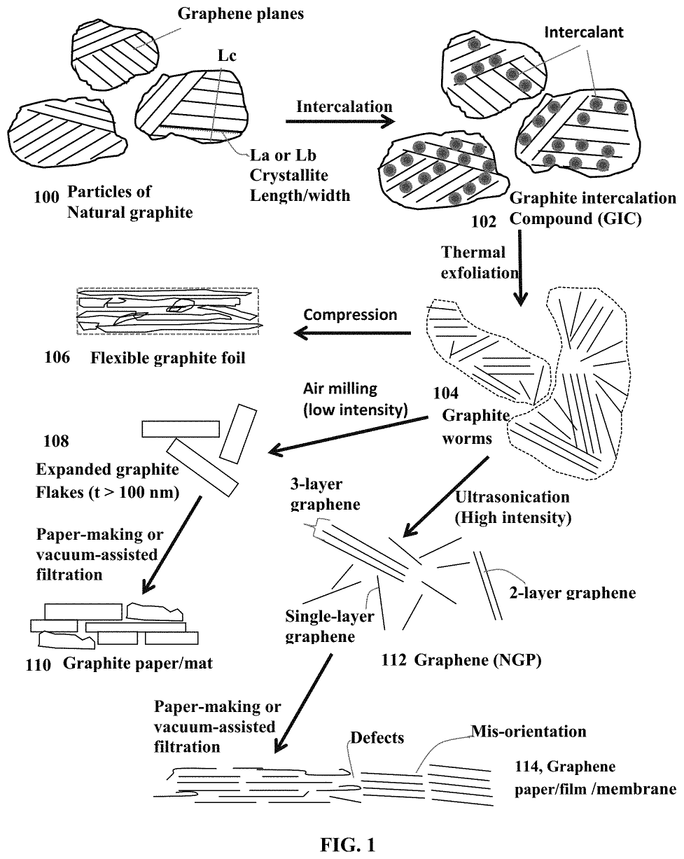

### DESCRIPTION OF THE PREFERRED EMBODIMENTS

The following includes definitions of various terms and phrases used throughout this specification.

The term “graphene” means a material comprising one or more planar sheets of bonded carbon atoms that are densely packed in a hexagonal crystal lattice in which carbon atoms are bonded together through strong in-plane covalent bonds, and further containing an intact ring structure throughout a majority of the interior. Preferably at least 80% of the interior aromatic bonds are intact. In the c-axis (thickness) direction, these graphene planes may be weakly bonded together through van der Waals forces. Graphene may contain non-carbon atoms at their edges or surface, for example OH and COOH functionalities. The term graphene includes pristine graphene, graphene oxide, reduced graphene oxide, halogenated graphene including graphene fluoride and graphene chloride, nitrogenated graphene, hydrogenated graphene, doped graphene, functionalized graphene, and combinations thereof. Typically, non-carbon elements comprise 0 to 25 weight % of graphene sheets. The term “doped graphene” encompasses graphene having less than 10% of a non-carbon element. This non-carbon element can include hydrogen, oxygen, nitrogen, magnesium, iron, sulfur, fluorine, bromine, iodine, boron, phosphorus, sodium, and combinations thereof. Graphene may comprise single-layer graphene or few-layer graphene, wherein the few-layer graphene is defined as a graphene platelet formed of less than 10 graphene planes. Graphene may also comprise graphene nanoribbons. “Pristine graphene” encompasses graphene sheets having essentially zero % of non-carbon elements. “Nanographene platelet” (NGP) refers to a graphene having a thickness from less than 0.34 nm (single layer) to 100 nm (multi-layer).

Graphene oxide refers to a graphene material comprising up to 53% oxygen by weight. Functional groups may be found primarily at the edges of graphene oxide platelets. Graphene oxide may comprise single-layer graphene oxide or few-layer graphene oxide, wherein the few-layer graphene is defined as a graphene platelet formed of less than 10 graphene planes. Graphene oxide platelets may have a lateral dimension of 100 nm, 500 nm, 1 μm, 2 μm or may be larger or smaller. Graphene oxide may be chemically reduced, for example by addition of ascorbic acid and exposure to a temperature of about 80° C., or may by thermally reduced by exposure to light, radiation, or a heat energy at a temperature from about 80° C. to 3300° C. Reference is made to U.S. Pat. No. 2,798,878A, issued Jul. 9, 1957 for a complete description of a method of preparing graphene oxide (the Hummers Process), applicable in the instant disclosure.

The term “substantially” and its variations are defined as being largely but not necessarily wholly what is specified as understood by one of ordinary skill in the art, and in one non-limiting embodiment substantially refers to ranges within 10%, within 5%, within 1%, or within 0.5% of a referenced range.

Other objects, features and advantages of the present disclosure may become apparent from the following figures, description, and examples. It should be understood, however, that the figures, description, and examples, while indicating specific embodiments of the disclosure, are given by way of illustration only and are not meant to be limiting. In further embodiments, features from specific embodiments may be combined with features from other embodiments.

The disclosure provides a process for producing a translucent or opaque graphene oxide-filled polymer film having a low dielectric constant. The film may be amber, brown or black in color. The polymer film may contain polyimide.

Herein presented is a process for producing a graphene oxide-filled polymer film comprising the steps of:
(a) mixing graphene oxide platelets with a polymer precursor, a liquid (e.g. water or other solvent), and an optional curing agent to obtain a slurry;
(b) forming the slurry into a graphene oxide-filled precursor polymer composite film;
(c) optionally partially or completely removing the liquid from the wet film to form a precursor polymer composite film; and
(d) initiating a cure reaction of the graphene oxide-filled precursor polymer composite film.

The mixing step (a) can be accomplished by dissolving a polymer, monomer, oligomer, polymer precursor material (e.g. polyimide precursor material) in a solvent to form a solution and then dispersing graphene oxide in the solution to form a suspension or slurry. Typically, the polymer is in the amount of 0.1%-30% by weight in the polymer-solvent solution prior to mixing with graphene sheets. The amount of polymer may be 5%, 10% or 15% in the slurry. Preferably, the amount of polymer may be 20% to 25% by weight. The graphene oxide platelets may occupy 1% to 30% (more typically 3% to 20% and most desirably 5%-10%) by weight of the slurry. A high shear mixer may be used for this process. Heat may be applied to the slurry during the mixing process, to a temperature less that 75° C. Preferably, the slurry may be heated to 50° C. to 65° C. during mixing. More preferably, the slurry may be heated to 55° C. to 60° C. during mixing. The mixing time may be 10 minutes to 24 hours. More preferable, 1 hour to 4 hours. Graphene oxide may be added to the slurry prior to adding the polymer, after adding the polymer, or simultaneously. The slurry may also be created by dissolving a graphene oxide-polymer composite, or by dissolving a graphene oxide-polymer precursor composite.

The polymer precursor material may be selected from the group consisting of a precursor (e.g. monomer or oligomer) to polyimide, polyamide, polyoxadiazole, polybenzoxazole, polybenzobisoxazole, polythiazole, polybenzothiazole, polybenzobisthiazole, poly(p-phenylene vinylene), polybenzimidazole, polybenzobisimidazole, precursors thereof, derivatives, thereof, and combinations thereof. The polymer precursor material may be 3,4′-oxydianiline. The polymer precursor material may be an aromatic diamines, aliphatic diamines, or mixture thereof in combination with an aromatic dianhydrides.

The polymer precursor material may be a polyimide precursor material. Polyimide precursor materials may include aromatic diamines, aliphatic diamines, and mixtures thereof in combination with aromatic dianhydrides. Polyimide precursor materials may include a catalyst or a dehydrating agent. Polyimide precursor materials may include 3,4′-oxydianiline (ODA) combined with pyromellitic dianhydride (PMDA) in substantially a 1:1 molar ratio to create polyamic acid. Reference is made to U.S. Pat. No. 3,179,634 (issued Apr. 20, 1965); U.S. Application No. 2012/0308741A1 (published Dec. 6, 2012); and U.S. Application No. 2014/0228513 (published Aug. 14, 2014) for description of some typical polyimide precursor materials, applicable in the instant disclosure. Polyimide precursor materials may include a diamine selected from 3,4′-oxydianiline, 4,4′-oxydianiline, 1,4-diaminobenzene, 1,3-diaminobenzene, 4,4′-diaminobiphenyl, 4,4′-diaminodiphenyl sulfide, 2,2′-bis(trifluoromethyl)benzidene, 4,4-diamino-diphenyl ether, benzidine, 4,4-diamino diphenyl propane, 4,4′-diamino diphenyl methane, 4,4′-diamino diphenyl ether, 4,4′-diamino diphenyl sulfone, 4,4′-diamino diphenyl diethyl-silane, 4,4-diamino diphenyl phenylphosphine oxide, 4,4′-diamino diphenyl N-methylamine, 4,4′-diamino diphenyl sulfide, 4,4-diamino-diphenyl phenyl phosphonate and 4,4′-diamino diphenyl diethylsiloxane, 1,3-bis-(4-aminophenoxy)benzene, derivitaves thereof, and combinations thereof.

Polyimide precursor materials may include 1,2,3,4-cyclopentanetetracarboxylic acid dianhydride (CPDA), 5-diaminobenzoic acid, 2,4-diaminobenzenesulfonic acid, 1,10-diaminodecane, 1,12-diaminododecane, 1,13-diaminotridecane, 1, 14-diaminotetradecane, 1,2,5,6-naphthalenetetracarboxylic, 1, 2-diaminoethane, 1, 3-diaminopropane, 1, 4-diaminobutane, 1, 5-diaminopentane, 1, 7-diaminoheptane, 1, 8-diaminooctane, 1, 9-diaminonane, 1,1-bis(2,3-dicarboxyphenyl)ethane dianhydride, 1,2,5,6-naphthalene tetracarboxylic dianhydride, 1,2-diaminobenzene, 1,3-bis-(4-aminophenoxy)benzene, 1,3-diaminobenzene, 1,3-diaminocyclohexane, 1,4-diaminocyclohexane, 1,4-bis(aminophenoxy)benzene (TPE-Q), 1,4-diaminobenzene (PPD), 1,5-diamino naphthalene, 2-(methacryloyloxy)ethyl 3,5-diaminobenzoate, 2,2′, 3, 3′-benzophenone tetracarboxylic acid, 2,2′, 3,3′-biphenyltetracarboxylic acid, 2,2,4- and 2, 4,4-trimethyl-hexamethylene diamine, 2,2′,3,3′-biphenyl tetracarboxylic dianhydride, 2,2′-bis(trifluoromethyl)benzidene, 2,2′-bis-(3,4 bicarboxyphenyl) hexafluoropropane tetracarboxylic, 2,2-bis(3,4-dicarboxyphenyl) propane dianhydride, 2,2-bis(3,4-dicarboxyphenyl)hexafluoropropane, 2,2-bis(aminophenoxyphenyl)hexafluoropropane (HFBAPP), 2,2-bis(aminophenoxyphenyl)propane (BAPP), 2,2-bis(aminophenyl)hexafluoropropane (HFDA), 2,5-diaminobenzenesulfonic acid, 2,5-dimethyl-hexamethylenediamine, 2-methyl-1, 5-diaminopentane, 3,3′,4,4′-benzophenonetetracarboxylic acid, 3,3′,4,4′-biphenyltetracarboxylic acid, 3,3′,4,4′-biphenyl tetracarboxylic dianhydride, 3,3′,4,4′-diphenyl sulfone tetracarboxylic dianhydride, 3,3′-diamino diphenyl sulfone, 3,3′-dichlorobenzidine, 3,4,9, 10-perylenetetracarboxylic acid, 3,4,9, 10-perylenetetracarboxylic dianhydride, 3,4′-oxydianiline, 3,5-diaminophenyl cinnamate, 3-methyl-hexamethylene diamine, 4-(2,5-dioxotetrahydrofuran-3-yl)-tetralin-1,2-dicarboxylic acid anhydride (DOTDA), 4,4′-diamino diphenyl diethylsilane, 4,4′-diamino diphenyl ethyl phosphine oxide, 4,4′-diamino diphenyl methane, 4,4′-diamino diphenyl N-methyl amine, 4,4′-diamino diphenyl N-phenyl amine, 4,4′-diamino diphenyl silane, 4,4′-diamino diphenyl sulfone, 4,4′-diaminobiphenyl, 4,4′-diaminodiphenyl propane, 4,4′-diaminodiphenyl sulfide, 4,4′-oxydianiline, 4,4′-oxydiphthalic anhydride, 4,4-methylenedianiline (MDA), 4,4-oxydianiline (ODA), 4′-biphenyltetracarboxylic acid, 5-methyl-1, 9-diaminononane, 9,9′-bis(4-amino)fluorine, acetic anhydride, benzenetetracarboxylic dianhydride, benzidine, bicyclooct-7-ene-2,3,5,6-tetracarboxylic acid dianhydride (BODA), biphenyltetracarboxylic dianhydride, bis(2,3-dicarboxyphenyl) methane dianhydride, bis(3,4-dicarboxyphenyl) sulfone dianhydride, bis(aminopropyl) tetramethyl-disiloxane, bisphenol A dianhydride, cyclobutane dianhydride, cyclobutanetetra-carboxylic acid dianhydride (CBDA), cyclohexane diamine, diethylenetriaminepentaacetic dianhydride (DTPA), dodecane diamine, hexamethylene diamine, mellitic acid dianhydride (MADA), meta-bis(aminophenoxydiphenyl)sulfone (m-BAPS), meta-phenylenediamine (m-PDA), naphthalenetetracarboxylic dianhydride, oxydibenzoic dianhydride, oxydiphthalic anhydride (ODPA), oxydiphthalic dianhydride, para-bis(aminophenoxydiphenyl)sulfone (p-BAPS), phthalic anhydride, pyridine, pyromellitic acid, pyromellitic dianhydride (PMDA), derivatives thereof, and combinations thereof.

The slurry of step (a) may further comprise a polymer matting agent or a coloring agent. Polymer matting agents may include nanoscaled inorganic particles, carbon black, finely ground polymer particles, and combinations thereof. Silica and surface-treated silica may be used as matting agents, optionally in combination with other matting agents. Reference is made to U.S. Pat. No. 8,574,720 (issued Nov. 5, 2013) for complete description of matting agents for polymer films, and methods of using said matting agents, applicable in the instant disclosure.

The slurry of step (a) may further comprise a graphene additive or a carbon nanotube additive.

The solvent of mixing step (a) may comprise water, acetone, γ-butyrolactone, chlorobenzene, cyclopentyl methyl ether, dihydrolevoglucosenone (Cyrene), dimethylacetamide (DMAc), ethanol, N-methyl-2-pyrrolidone (NMP), hexafluorisopropanol (HFIP), butylated hydroxytoluene (BHT), dimethylformamide (DMF), dimethylsulfoxide (DMSO), methanol, methyl acetate, methyl ethyl ketone, methylene chloride, piperazine, sodium trifluoroacetate (NaTFA), tert-butanol, tetrahydrofuran (THF), 1,2,4-trichlorobenzene (TCB), triethylamine (TEA), triethyl phosphate, toluene, derivatives thereof, and mixtures thereof.

The solvent of mixing step (a) may comprise a solvent pair, including cyclohexanone-methanol, cyclohexanone-ethanol, cyclopentanone-methanol, cyclopentanone-ethanol, γ-butyrolactone-methanol, γ-butyrolactone-ethanol, γ-butyrolactone-water, γ-valerolactone-methanol, γ-valerolactone-ethanol, and γ-valerolactone-water, as taught in Duereh et al. “Replacement of hazardous chemicals used in engineering plastics with safe and renewable hydrogen-bond donor and acceptor solvent-pair mixtures” ACS Sustainable Chemistry & Engineering 3.8 (2015): 1881-1889. The solvent of mixing step (a) may comprise a solvent pair of tetrahydrofuran (THF) and methanol.

The film-forming step (b) can be conducted by casting or coating the slurry into a thin film on a solid substrate such as PET film or glass plate. The film-forming process may optionally be carried out under the influence of an orientation-inducing stress field, for example by coating or casting the slurry with a doctor blade to form a thin film of desired thickness. In a coating procedure, the shear stress may be created by extruding the dispensed slurry through a coating die over a supporting flexible PET substrate. The film may also be formed by slot die, comma coater, pair reverse-rotating rollers, spray coating, spin coating, or screen printing. The film may be formed by extruding the slurry into a bath of cure agents or conversion chemicals. The wet film may be from 5 μm to 100 μm in thickness prior to drying, or it may be thicker or thinner. The wet film may preferably be 10 μm, 20 μm, 50 μm or 70 μm in thickness.

Advantageously, the coating process can be a continuous, roll-to-roll process that is fully automated. The cast or coated film is initially in a wet state and the liquid component may be substantially removed after coating or casting.

Step (c) of partially or completely removing the solvent liquid may be carried out by heat, ventilation, or by vacuum. This step may be carried out at a temperature from 25° C. to 300° C.

Step (d) of initiating a cure reaction may be carried out by exposure to chemicals, by exposure to heat, by exposure to radiation, by exposure to microwaves, by exposure to light, or by combinations thereof. Heat treatment to initiate a cure reaction may involve heating the film to a temperature from 100° C. to 500° C. for a period of time sufficient to effect crosslinking of the polymer precursor to the graphene oxide, to obtain a graphene oxide-filled polymer film. The heat treatment time may be from 1 minute to 24 hours. The heat treatment time may be 5 minutes, 10 minutes, 1 hour, or may be longer or shorter. Higher heat treatment temperatures require shorter heat treatment times. Preferably, the heat treatment may be selected from 150° C. to 400° C. Preferably, the heat treatment may be carried out at 350° C. for 3 to 10 minutes. Heat treatment may be carried out in vacuum, in an inert gas atmosphere, or in standard atmospheric conditions. The finished film may be from 1 μm to 200 μm in thickness prior to drying, or it may be thicker or thinner. The finished film may preferably be 5 μm, 10 μm, 15 μm, 40 μm, 60 μm, 80 μm, or 100 μm in thickness.

For a polyimide film, the step of initiating a cure reaction may cause imidization of the slurry. The reaction may be allowed to progress to from 60% completion of imidization to 100% completion of imidization. Preferably, the reaction may be allowed to progress to substantially 80% completion, substantially 90% completion, or to substantially 95% completion.

The steps of coating, optionally drying, and initiating a cure reaction may be repeated one or more times to create a thicker composite film. The steps of coating, and drying may be repeated one or more times to create a thicker composite film. The composition of the slurry may be varied between coating steps to create a composite film having layers with varying properties.

Optionally, the graphene oxide-filled polymer film may be stretched before, during or after initiation of the cure reaction.

Optionally, the graphene oxide-filled polymer film may be compressed before, during or after the initiation of the cure reaction. The graphene oxide-filled polymer film may be peeled from the substrate or may remain with the substrate.

Graphene oxide-filled polymer films made from this process may have a tensile strength from 80 MPa to 160 MPa, or may be higher or lower. These films may have a tensile modulus from 2 to 3.5 GPa, or may be higher or lower. Graphene oxide-filled polymer film may have a dielectric strength from about 3000 V/mil to about 7000 V/mil, or may be higher or lower. Preferably, the dielectric strength may be greater than 5000 V/mil. Preferably, the graphene oxide-filled polymer film is opaque and has a matte surface finish.

Optionally, graphene oxide films prepared by the disclosed process may be heat treated (carbonized) to increase the thermal or electrical conductivity. Reference is made to U.S. Patent Application No. 20150266739 (published Sep. 24, 2015) for complete description of methods for heat treating polymer films, applicable in the instant disclosure.

A similar process may be used to produce other types of filled polymers. For instance, a process for producing a graphene platelet-filled polymer film may comprise the steps of: (a) mixing graphene platelets or expanded graphite platelets with a polymer precursor material and a liquid to form a slurry, wherein the graphene platelets are selected from graphene oxide, reduced graphene oxide, chemically reduced graphene oxide, fluorinated graphene, hydrogenated graphene, nitrogenated graphene, doped graphene, chemically functionalized graphene, or a combination thereof; (b) forming the slurry into a wet film; (c) optionally partially or completely removing the liquid from the wet film to form a precursor polymer composite film; and (d) initiating a cure reaction of the film to obtain a graphene platelet-filled composite film.

Heat may be applied to the slurry during the mixing process, to a temperature less that 75° C. Preferably, the slurry may be heated to 50° C. to 65° C. during mixing. More preferably, the slurry may be heated to 55° C. to 60° C. during mixing. The mixing time may be 10 minutes to 24 hours. More preferable, 1 hour to 4 hours.

The polymer may be selected from the group consisting of polyimide, polyamide, polyoxadiazole, polybenzoxazole, polybenzobisoxazole, polythiazole, polybenzothiazole, polybenzobisthiazole, poly(p-phenylene vinylene), polybenzimidazole, polybenzobisimidazole, and combinations thereof.

The following examples are presented to illustrate the best modes of practicing the instant disclosure, and not to be construed as limiting the scope of the instant disclosure:

### Example 1: Preparation of Polybenzoxazole (PBO) Films, NGP-PBO Films, and Expanded Graphite Flake-PBO Films

Polybenzoxazole (PBO) films were prepared via casting and thermal conversion from its precursor, methoxy-containing polyaramide (MeO-PA). Specifically, monomers of 4, 4′-diamino-3,3′-dimethoxydiphenyl (DMOBPA), and isophthaloyl dichloride (IPC) were selected to synthesize PBO precursors, methoxy-containing polyaramide (MeO-PA) solution. This MeO-PA solution for casting was prepared by polycondensation of DMOBPA and IPC in DMAc solution in the presence of pyridine and LiCl at −5° C. for 2 hr, yielding a 20 wt % pale yellow transparent MeO-PA solution. The inherent viscosity of the resultant MeO-PA solution was 1.20 dL/g measured at a concentration of 0.50 g/dl at 25° C. This MeO-PA solution was diluted to a concentration of 15 wt % by DMAc for casting.

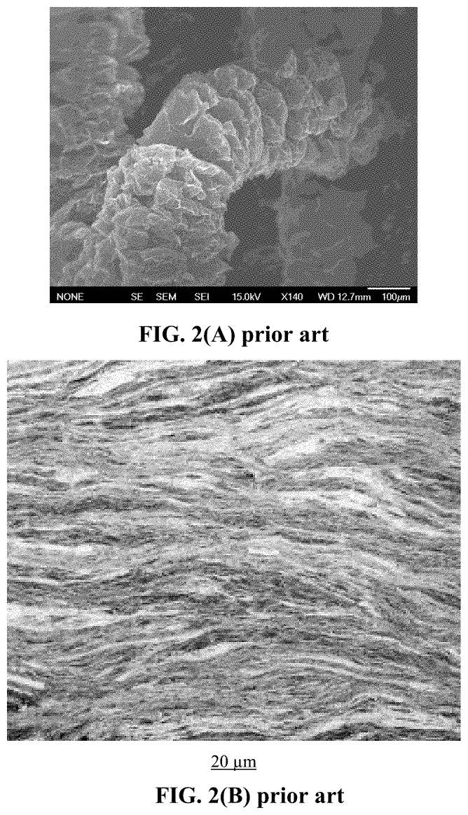

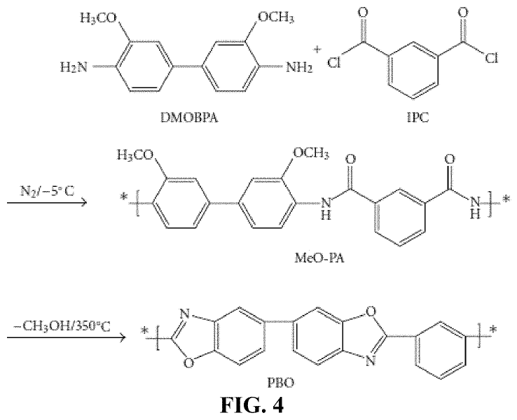

The as-synthesized MeO-PA was cast onto a glass surface to form thin films (35-120 μm) under a shearing condition. The cast film was dried in a vacuum oven at 100° C. for 4 hr to remove the residual solvent. Then, the resulting film with thickness of approximately 28-100 μm was treated at 200° C.-350° C. under N₂ atmosphere in three steps and annealed for about 2 hr at each step. This heat treatment serves to thermally convert MeO-PA into PBO films. The chemical reactions involved may be illustrated in FIG. 4. For comparison, both NGP-PBO and expanded graphite flake-PBO films were made under similar conditions. The NGP or expanded graphite flake proportions were varied from 10% to 90% by weight. A typical expanded graphite flake is shown in FIG. 2(A).

### Example 2: Preparation of Polyimide (PI) Films, Graphene Oxide-Filled Polyimide Films, and the Heat-Treated Versions Thereof

The synthesis of conventional polyimide (PI) involved poly(amic acid) (PAA, Sigma Aldrich) formed from pyromellitic dianhydride (PMDA) and oxydianiline (ODA). Prior to use, both chemicals were dried in a vacuum oven at room temperature. PMDA and ODA were added to a solvent solution and stirred for 5° C. to form PAA. Graphene oxide (20% by weight suspended in DMAC) was added, and the slurry was stirred for 1 to 4 hours using a magnetic stir bar, while heating to a temperature greater than 55° C. Subsequently, the viscous polymer solution was cast onto a polymer film or glass substrate, partially dried, and heat treated to create an opaque, flexible black film having a thickness of about 12 μm. Multiple films were created, having thicknesses from 10 to 25 μm.

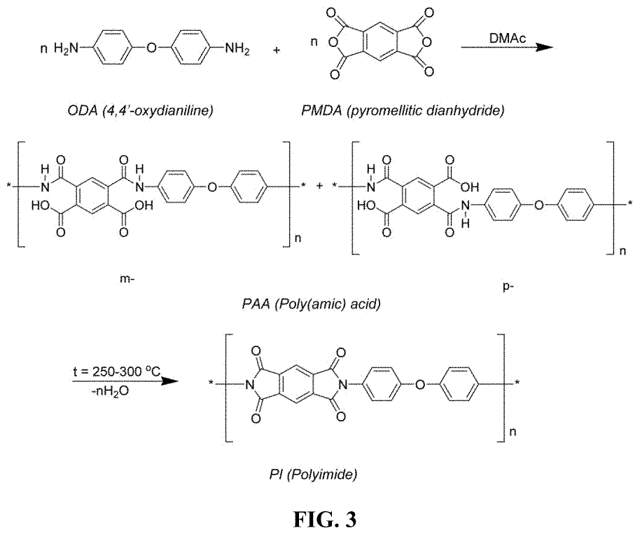

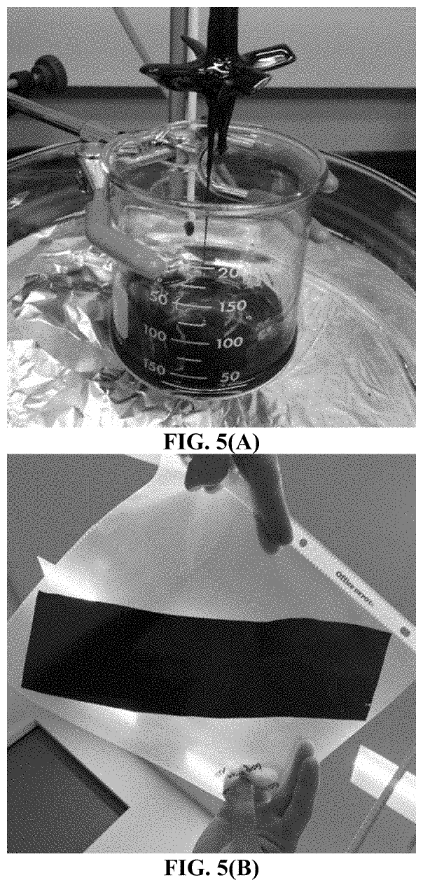

Representative chemical reactions involved in the formation of polyimide polymers from precursors (monomers or oligomers) are given in FIG. 3. A typical mixing step and a resulting film are shown in FIG. 5(A) and FIG. 5(B).

### Example 3: Preparation of Polybenzimidazole (PBI) Films and NGP-PBI Films

PBI is prepared by step-growth polymerization from 3,3′,4,4′-tetraaminobiphenyl and diphenyl isophthalate (an ester of isophthalic acid and phenol). The PBI used in the present study was obtained from PBI Performance Products in a PBI solution form, which contains 0.7 dl/g PBI polymer dissolved in dimethylacetamide (DMAc). The PBI and NGP-PBI films were cast onto the surface of a glass substrate.

Scanning electron microscopy (SEM), transmission electron microscopy (TEM) pictures of lattice imaging of the graphene layer, as well as selected-area electron diffraction (SAD), bright field (BF), and dark-field (DF) images were also conducted to characterize the structure of various graphitic film materials. A close SEM scrutiny of the graphene-polymer composite films indicates that the graphene platelets in a composite film herein disclosed are substantially oriented parallel to one another. The inclination angles between graphene platelets in the inventive films are mostly less than 5 degrees. In contrast, flexible graphite foil has many folded graphite flakes, kinks, and mis-orientations, with many of the angles between two graphite flakes are greater than 10 degrees, some as high as 45 degrees, as shown in (FIG. 2(B).

1. A process for producing a graphene oxide platelet-filled polyimide film comprising the steps of:
a) mixing graphene oxide platelets with a polyimide precursor material and a liquid to form a slurry, wherein said slurry further comprises a monomer, an oligomer, a polymer, a dehydrating agent, a photosensitizer, a cure agent, an anhydride, a diamine or a combination thereof, wherein said anhydride is selected from benzenetetracarboxylic dianhydride, biphenyltetracarboxylic dianhydride, diethylenetriaminepentaacetic dianhydride (DTPA), ethylenediaminetetraacetic dianhydride (EDTA), mellitic acid dianhydride (MADA), naphthalenetetracarboxylic dianhydride, oxydibenzoic dianhydride, oxydiphthalic anhydride (ODPA), phthalic anhydride, pyromellitic dianhydride (PMDA), derivatives thereof, and combinations thereof and wherein said diamine is selected from 3,4′-oxydianiline, 4,4′-oxydianiline, 1,4-diaminobenzene, 1,3-diaminobenzene, 4,4′-diaminobiphenyl, 4,4′-diaminodiphenyl sulfide, 2,2′-bis(trifluoromethyl)benzidene, benzidine, 4,4-diamino diphenyl propane, 4,4′-diamino diphenyl methane, 4,4′-diamino diphenyl sulfone, 4,4′-diamino diphenyl diethyl-silane, 4,4-diamino diphenyl phenylphosphine oxide, 4,4′-diamino diphenyl N-methylamine, 4,4′-diamino diphenyl sulfide, 4,4-diamino-diphenyl phenyl phosphonate and 4,4′-diamino diphenyl diethylsiloxane, 1,3-bis-(4-aminophenoxy)benzene, derivatives thereof, and combinations thereof;
b) forming a wet film from said slurry; and
c) imidizing said film to substantially 90% or more completion of the crosslinking reaction, to obtain a graphene oxide platelet-filled composite film;
wherein said imidizing step affects crosslinking of said polyimide and chemical bonding of said polyimide to said graphene oxide platelets.

2. The process of claim 1, wherein said step of forming said slurry into a wet film is carried out by a doctor blade, slot die coating, comma coating, reverse-rollers coating, spray coating, spin coating, or screen printing and said step is optionally under the influence of an orientation-inducing stress field to align said graphene oxide platelets on a solid substrate.

3. The process of claim 24, wherein said step of partially or completely removing said liquid from said wet film is carried out in vacuum, in an inert atmosphere, in a ventilation environment, or at a temperature from 25° C. to 300° C.

4. The process of claim 1, wherein said imidizing step is carried out by exposure to a temperature from 100° C. to 500° C. for a period of time sufficient to affect crosslinking of said polymer and chemical bonding of said polymer to said graphene oxide platelets, by exposure to light, by exposure to microwave energy, by exposure to radiation, or by combinations thereof.

5. The process of claim 4, wherein said period of time is from 1 minute to 4 hours.

6. The process of claim 1, further comprising a step of compressing or stretching said graphene oxide platelet-filled polyimide film during or after said step (d) of imidizing said graphene oxide platelet-filled polyimide film.

7. The process of claim 1, further comprising a step of adding one or more additional layers of graphene oxide platelet-filled polyimide film after completing a first layer of graphene oxide platelet-filled polyimide film, where said one or more additional layers have the same chemical composition as said first layer or have a different chemical composition.

8. The process of claim 1, further comprising a step of adding one or more additional layers of precursor polyimide composite film after completing a first layer of precursor polyimide composite film, where said one or more additional layers have the same chemical composition as said first layer, or have a different chemical composition.

9. The process of claim 1, carried out as a continuous or roll-to-roll process.

10. The process of claim 1, wherein said polyimide precursor material is selected from aromatic diamines, aliphatic diamines, and mixtures thereof in combination with aromatic dianhydrides.

11. (canceled)

12. The process of claim 1, wherein said liquid comprises water, acetone, γ-butyrolactone, chlorobenzene, cyclopentyl methyl ether, dihydrolevoglucosenone, dimethylacetamide (DMAc), ethanol, N-methyl-2-pyrrolidone (NMP), hexafluorisopropanol (HFIP), butylated hydroxytoluene (BHT), dimethylformamide (DMF), dimethylsulfoxide (DMSO), methanol, methyl acetate, methyl ethyl ketone, methylene chloride, piperazine, sodium trifluoroacetate (NaTFA), tert-butanol, tetrahydrofuran (THF), 1,2,4-trichlorobenzene (TCB), triethylamine (TEA), triethyl phosphate, toluene, derivatives thereof, and mixtures thereof.

13. The process of claim 1, wherein said slurry further comprises a matting agent, a colorant, a reinforcement material or other additive at total non-graphene oxide additive weight of 0.1 weight percent to 15 weight percent of the total weight of the dried film.

14. A graphene oxide platelet-filled polyimide film made by the process of claim 1, having a thickness from 1 μm to 200 μm.

15. The graphene oxide platelet-filled polyimide film of claim 14, wherein the graphene oxide platelets are substantially parallel to each other and the film has a tensile strength from 80 MPa to 160 MPa and/or a tensile modulus from 2 to 3.5 GPa.

16. The graphene oxide platelet-filled polyimide film of claim 14 having a dielectric strength greater than 5000 V/mil.

17. The graphene oxide platelet-filled polyimide film of claim 14, having a dielectric strength from 3000 V/mil to 7000 V/mil.

18. The graphene oxide platelet-filled polyimide film of claim 14, having layers of varying composition.

19. A process for producing a graphene platelet-filled polymer film comprising the steps of:
a) mixing graphene platelets with a polymer precursor material and a liquid to form a slurry, while optionally heating the slurry to a temperature between 50° C. to 65° C., wherein said graphene platelets are selected from reduced graphene oxide, chemically reduced graphene oxide, fluorinated graphene, hydrogenated graphene, nitrogenated graphene, doped graphene, chemically functionalized graphene, and combinations thereof;
b) forming said slurry into a wet film;
c) partially or completely removing said liquid from said wet film to form a precursor polymer composite film; and
d) initiating a cure reaction of said film to obtain a graphene platelet-filled composite film wherein said cure reaction affects crosslinking of said polymer precursor material and chemical bonding of said polymer precursor material to said graphene platelets.

20. A process for producing a graphene platelet-filled polymer film comprising the steps of:
a) mixing graphene platelets with a polymer precursor material and a liquid to form a slurry, while optionally heating the slurry to a temperature between 50° C. to 65° C., wherein said graphene platelets are selected from graphene oxide, reduced graphene oxide, chemically reduced graphene oxide, fluorinated graphene, hydrogenated graphene, nitrogenated graphene, doped graphene, chemically functionalized graphene, and combinations thereof, wherein said polymer is selected from the group consisting of polyamide, polyoxadiazole, polybenzoxazole, polybenzobisoxazole, polythiazole, polybenzothiazole, polybenzobisthiazole, poly(p-phenylene vinylene), polybenzimidazole, polybenzobisimidazole, and combinations thereof;
b) forming said slurry into a wet film;
c) partially or completely removing said liquid from said wet film to form a precursor polymer composite film; and
d) initiating a cure reaction of said film to obtain a graphene platelet-filled composite film wherein said cure reaction affects crosslinking of said polymer precursor material and chemical bonding of said polymer precursor material to said graphene platelets.

21. The process of claim 19, wherein said step of forming said slurry into a wet film is carried out by a doctor blade, slot die coating, comma coating, reverse-rollers coating, spray coating, spin coating, or screen printing and said step is optionally under the influence of an orientation-inducing stress field to align said graphene platelets on a solid substrate.

22. The graphene platelet-filled polymer film produced by the process of claim 21, wherein said graphene platelets are substantially parallel to one another.

23. The process of claim 1, wherein step a includes heating the slurry to a temperature between 50° C. to 65° C.

24. The process of claim 1, wherein the process further includes, prior to said imidizing step, partially or completely removing said liquid from said wet film to form a precursor polyimide composite film.

25. The process of claim 1, wherein:
step a includes heating the slurry to a temperature between 50° C. to 65° C.; and
the process further includes partially or completely removing said liquid from said wet film to form a precursor polyimide composite film.
